(19) United States
(12) Patent Application Publication
(10) Pub. No.: US 2024/0288850 A1
(43) Pub. Date: Aug. 29, 2024

(54) ADAPTIVE TUNING FOR MULTI-ASIC SYSTEMS

(71) Applicant: Intel Corporation, Santa Clara, CA (US)

(72) Inventors: Long SHENG, Shanghai (CN); Liang CHEN, Shanghai (CN); Tao ZHOU, Oceanside, CA (US); Shuping HAN, Shanghai (CN); Yan WANG, Shanghai (CN); Chandra KATTA, Cupertino, CA (US); Vikram SURESH, Portland, OR (US); Chong HAN, Shanghai (CN); He HAN, Shanghai (CN); Tatt Hee OONG, Jelutong (MY); Chee Hung CHIAN, Bayan Lepas (MY); Yi HAN, Shanghai (CN); Hao CHEN, Shanghai (CN)

(73) Assignee: Intel Corporation, Santa Clara, CA (US)

(21) Appl. No.: 18/571,672

(22) PCT Filed: Apr. 26, 2022
(86) PCT No.: PCT/US2022/026405

§ 371 Date: Dec. 18, 2023

(30) Foreign Application Priority Data
Dec. 27, 2021 (WO) PCT/CN2021/141497
Dec. 27, 2021 (WO) PCT/CN2021/141508

(51) Int. Cl. G05B 19/4155; H05K 7/20

(52) U.S. Cl. CPC G05B 19/4155; H05K 7/20209; G05B 2219/50333

(57) ABSTRACT

Various embodiments are directed to frequency and voltage tuning for systems with multiple application-specific integrated circuits (ASICs) and disclosed herein may be applied to multi-AIC systems in a variety of applications, such as high-performance computing, artificial intelligence, graphics applications, and cryptocurrency or blockchain mining functions.

### CROSS REFERENCE TO RELATED APPLICATION

The present application claims priority to: PCT Application No. PCT/CN2021/141508, which was filed Dec. 27, 2021; and to PCT Application No. PCT/CN2021/141497, which was filed Dec. 27, 2021.

### FIELD

Embodiments of the present disclosure relate generally to the technical field of electronic circuits. In particular, some embodiments are directed to frequency and voltage tuning for systems with multiple application-specific integrated circuits (ASICs).

### BACKGROUND

Computing devices increasingly utilize application-specific integrated circuits (ASICs) to provide customized functionality in various applications, such as high-performance computing, artificial intelligence, graphics applications, and cryptocurrency mining. However, due to inherent variances in silicon manufacturing technology, it is not guaranteed that multiple ASICs will have identical characteristics. In particular, different ASICs may exhibit different performance and power behaviors in operation, thus making it challenging to achieve optimal power and performance in multi-ASIC systems. Embodiments of the present disclosure address these and other issues.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 illustrates an example of a multi-ASIC system in accordance with various embodiments.

FIG. 2A is a block diagram of a procedure and associated circuitry for adaptive tuning in a multi-ASIC system, in accordance with various embodiments.

FIG. 2B illustrates an example of a procedure for adaptive tuning in a multi-ASIC system, in accordance with various embodiments.

FIG. 3A illustrates an example of a procedure for adjusting voltage supplied to a multi-ASIC system, in accordance with various embodiments.

FIG. 3B illustrates another example of a procedure for adjusting voltage supplied to a multi-ASIC system, in accordance with various embodiments.

FIG. 4 illustrates an example of a system configured to employ the apparatuses and methods described herein, in accordance with various embodiments.

FIG. 5 is a flow diagram illustrating a process for adaptive tuning in a multi-ASIC system in accordance with various embodiments.

### DETAILED DESCRIPTION

In the following detailed description, reference is made to the accompanying drawings that form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The terms “substantially,” “close,” “approximately,” “near,” and “about,” generally refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group), a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

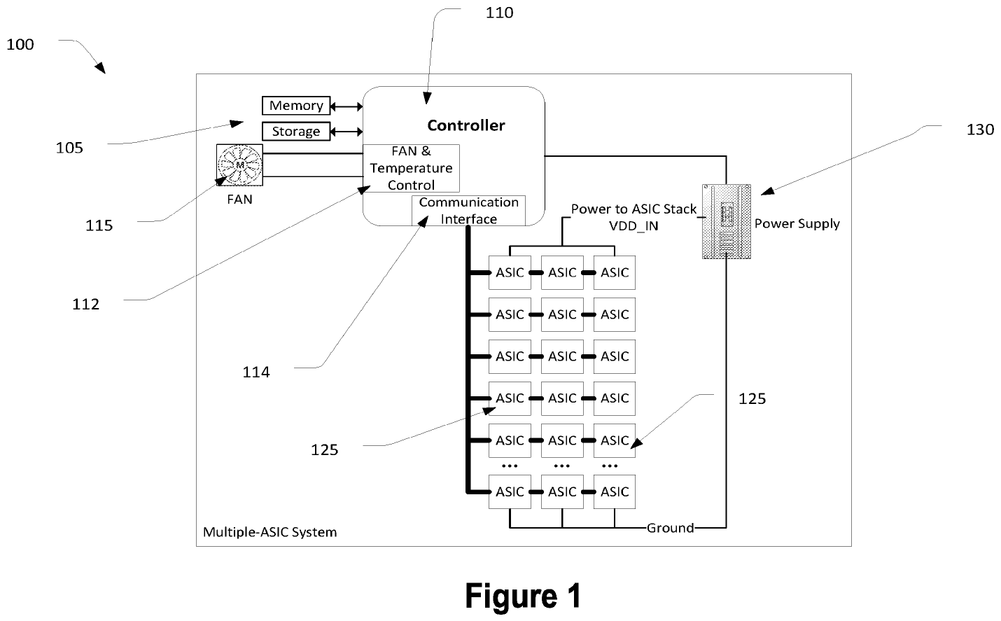

As introduced above, embodiments disclosed herein may be applied to multi-ASIC systems in a variety of applications, such as high-performance computing, artificial intelligence, graphics applications, and cryptocurrency or blockchain mining functions. FIG. 1 illustrates an example of a multi-ASIC system in accordance with various embodiments.

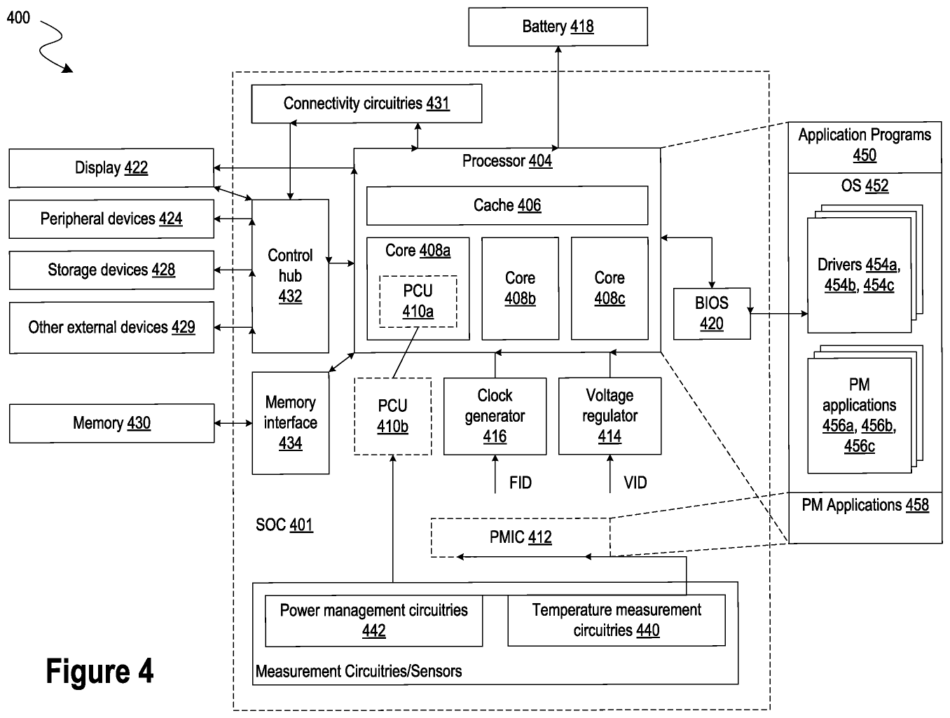

In the example depicted in FIG. 1, the multi-ASIC system 100 includes various components that may be assembled together in one chassis. The system 100 includes a controller 110 that includes, or is coupled to, one or more memory/storage devices 105. In some embodiments, the controller 110 may be implemented as part of a system, such as system 400 with some or all of the components shown in FIG. 4 and described in more detail below. For example, in some embodiments the controller 110 is implemented using a system on chip (SoC), such as SoC 401 in FIG. 4.

In the example shown in FIG. 1, controller 110 includes a fan and temperature control component 112 coupled to a fan 115 for adjusting the temperature (e.g., heating or cooling) a plurality of ASICs 125. The controller 110 is coupled to the plurality of ASICs via communication interface 114. The controller 110 is further coupled to power supply 130 to adjust the power supplied to the plurality of ASICs 125.

In some embodiments, the fan and temperature control component 112 may be coupled to additional (or different) cooling systems besides the fan 115. For example, some embodiments may include an immersion ASIC cooling system, comprising a dielectric cooling liquid, coupled to control component 112. Additionally or alternatively, some embodiments may include other forms of liquid cooling systems coupled to the temperature control component 112.

The controller 110 may communicate with the ASICS 125 via the communication interface 114, which may include a universal asynchronous receiver-transmitter (UART) in some embodiments. Via the communication interface 114, the controller 110 may perform the coarse frequency adjustment and fine frequency adjustment procedures for the ASICS 125 described in more detail below.

In some embodiments, ASICs may be populated on a plurality of different boards that operate independently of each other. In such embodiments, any suitable number of ASICs may be populated on each board, and each board may be monitored and controlled by controller 110. The system depicted in FIG. 1 and described herein is merely an example, and other system configurations may be used in accordance with various embodiments herein.

As noted above, due to inherent tolerance differences in silicon manufacturing technology, it cannot be guaranteed that multiple ASICs (such as ASICs 125) will have identical characteristics. For example, different ASICs may have different performance and power behavior when operated. In conventional multi-ASIC systems, these differences make it difficult to achieve optimal power and performance. For example, while there may be a cost savings with ASICs without a binning process, but at the expense of having diverged PnP behavior. Such costs are increased with binning enabled to get PnP consistency.

Additionally, utilizing higher voltages & frequencies can typically bring higher performance to each ASIC, but it also results in higher power consumption. Moreover, finding a balance between power and performance, especially across many ASICs which are not identical, presents a sizable challenge. An ASIC's impedance is also often varied with computing clock frequency changes, (e.g., the higher frequency, the lower impedance), particularly when all ASICs are designed in a power stacking mode (e.g., a few ASICs first connected in parallel as one stack, then multiple stacks are connected in series, with all stacks are sharing one input voltage). In such cases, one ASIC will impact the others in the same stack, and in different stacks, because they are sharing one input voltage.

Furthermore, an increased ASIC die temperature may lead to better pass rates (e.g., pass rates for hash functions solving blockchain/cryptocurrency computations), but current leakage will also increase, which causes a power increase. Accordingly, in multi-ASIC systems the power and performance of the entire system will be impacted by the system input voltage (if all ASICs are designed in power stacking mode and share one input power), individual running frequency of the ASICs (if they are designed in variable frequency), and ASIC/system thermal temperature. Optimizing power and performance becomes even more challenging if the ASIC is not binned during manufacturing.

Various embodiments herein may overcome these and other issues. For example, some embodiments herein provide an adaptive PnP tuning solution based on ASIC function pass rate (e.g., a hashing function for blockchain computations), which manipulates frequency tuning for individual ASIC, system input voltage tuning and system thermal temperature control.

Conventional systems, by contrast, do not provide PnP tuning solutions for multi-ASIC systems. Some conventional approaches include applying manufacturing ASIC performance binning where ASICs with similar performance and power are collected into the same bin, fixing their frequency with fuses. Added processing and screening is thus necessary in such cases to identify/sort the ASICs to try to improve power and performance, significantly increasing the cost of manufacturing, logistics, supply chain management and ODM manufacturing. It is also a business model challenge to setup customer support strategy with pricing on different bin ASIC.

In other conventional systems, the ASIC frequency is fixed. In such cases, the system software sets a fixed frequency to all ASICs during system initialization (usually compromising with the lowest suitable frequency for all ASICs) so that all the ASICs in one system will function correctly. However, to apply the fixed frequency to all ASICs in this manner means power and performance will be compromised significantly because the ASIC with the worst PnP characteristic has to be accommodated, thus limiting the performance of the entire group of ASICs.

Other conventional systems don't utilize a power stacking mode while supplying independent power/voltage to individual ASICs. However, this approach adds a significant system hardware cost because of the complexity of power supplies. Most of the time such a solution is infeasible in a multi-ASIC system designs.

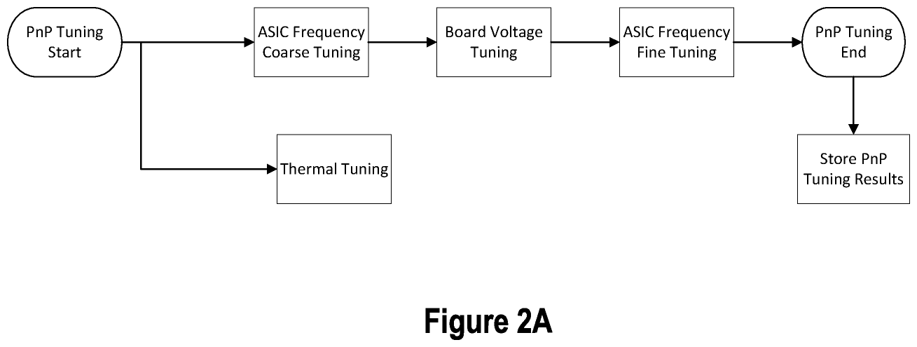

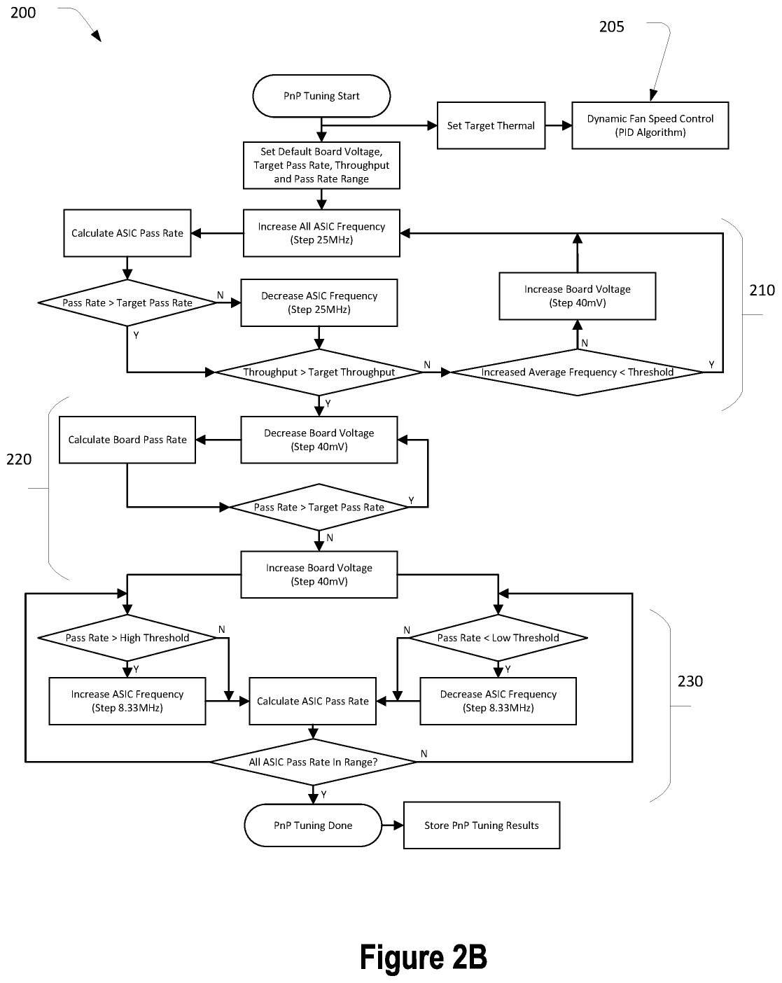

Various embodiments herein, by contrast, provide solutions that help to achieve optimal power efficiency while meeting a target throughput key performance indicator (KPI). Such solutions may include components across one or more of ASIC hardware (HW), power control unit, thermal management, and/or software (SW) in a system. Aspects in the SW which provide the ASIC pass rate based adaptive PnP tuning flow may include one or more of: (1) implementing dynamic voltage and frequency scaling (DVFS) in ASICs with software programmable registers, where software may control the ASIC computing frequency by programming the register; (2) smart power supply unit or a power supply with programmable output voltage control, where software can program to control the power supply output voltage to stacked ASICs; (3) a SW programmable system with fan speed control helps manage the system/ASIC temperature; and (4) an ASIC pass rate-based adaptive PnP tuning flow in control software, as introduced in FIG. 2A and described in more detail with respect to FIG. 2B.

As shown in the overview flow diagram of FIG. 2A, upon initiation of the tuning process (PnP Tuning Start), the system performs a dynamic thermal control process (Thermal Tuning) to keep the average temperature of a multi-ASIC system at or near a target temperature. Among other things, a suitable target temperature helps provide better pass rates for the multi-ASIC system. The system further applies a pass rate based tuning process for power and performance, in two phases.

In the first phase, coarse tuning (ASIC Frequency Coarse Tuning), the ASIC frequency is coarse adjusted (e.g., increased) in relatively large step amounts until system performance KPI achieved. A board input voltage tuning process (Board Voltage Tuning) is performed to adjust the voltage (e.g., decreased) supplied to the ASICs to meet system power efficiency KPI.

In the second phase, fine tuning (ASIC Frequency Fine Tuning), the system fine tunes the frequency of individual ASICs in relatively smaller step amounts compared to the coarse tuning in order to compensate the performance regression introduced in voltage coarse tuning.

As further illustrated in FIG. 2A, at the conclusion of the PnP tuning process (PnP Tuning End), the PnP tuning results (e.g., ASIC frequency, hash board input voltage) could be optionally saved into memory and be applied in the following system boot to help reduce the boot time.

Embodiments of the present disclosure provide a number of advantages over conventional systems and approaches. For example, some embodiments may help to reduce the ASIC manufacturing cost of applying ASIC binning process. Embodiments can also help improve a wafer's utilization rate and production yield rate. For example, ASICs with very diverged PnP characteristic can be neutralized in one system and the system still can achieve system level PnP KPIs.

Embodiments of the present disclosure may also provide a robust pass rate based PnP tuning solution to improve the power efficiency around 5%-10% with the same throughput. Some embodiments further provide a robust pass rate based PnP tuning solution to ramp up all ASICs work with suitable frequency, voltage and die temperature, improve the system stability to avoid ASIC damage by high die temperature or ASIC PLL unlocked. Embodiments of the present disclosure may be used in a variety of applications to help achieve optimal power efficiency and performance in multi-ASIC systems, including high-performance computing, artificial intelligence, graphics, or blockchain computation processing.

The pass rate based adaptive PnP tuning solution as described herein may further be described using terminology such as one or more of “without binning”, “voltage stacking”, “PnP tuning”, “frequency tuning,” and/or “voltage tuning.”

### FURTHER DETAILS OF VARIOUS EMBODIMENTS

Any suitable KPI or combination of KPIs may be utilized in conjunction with embodiments of the present disclosure. Such KPI(s) may depend on the specific application of the multi-ASIC system. This disclosure proceeds by describing an example for one application of a multi-ASIC system, namely for cryptocurrency mining.

In this example, there are two key KPIs defined for crypto mining system/product-throughput and power efficiency, which are calculated using Equation 1 and Equation 2 as shown below. In some embodiments, throughput may be expressed as a measure of hashes per second (more typically terahashes per second—TH/s). In some embodiments, for example, a target throughput may be set at 40 TH/s.

Throughput=Hash Rate*Pass Rate. Equation 1:

Power Efficiency=Power/Throughput. Equation 2:

In this crypto mining design, hash results generated from individual ASICs are sent back to the system controller (e.g., controller 110 in FIG. 1) and the software running on the system controller 110 can verify the correctness of the hash results. For an ideal system, all the hash results send back should be correct and there would be a 100% pass rate. In a real-world system, however, various factors such as insufficient supply voltage, above-normal operating frequency or insufficient working die temperature for a particular ASIC may occur. In such cases, the logic gates within the mining ASICs will not be able to toggle correctly, or they toggle too late and cause errors, causing the pass rate to fall below 100%, then it is calculated by Equation 3 as follows.

Pass Rate=Number of Correct Results/Number of Total Results. Equation 3:

In this example, the pass rate is a key indicator for ASIC work status. If a pass rate for one ASIC from the plurality of ASICs isn't lower than the target pass rate, this may indicate the ASIC can work at a higher frequency. Otherwise, the system may need to decrease frequency, or increase voltage, to improve the ASIC pass rate.

In some embodiments, given a fixed supply voltage for individual ASICs, a maximum throughput may not necessarily occur when the pass rate is 100%. Instead, the maximum throughput may occur when the pass rate is less than 100% (e.g., about 97.5%). In such cases, the system may intentionally over-drive the operating frequency slightly higher to achieve a 97.5% pass rate to achieve optimal performance.

In multi-ASIC systems such as in this example, it is impossible to directly control individual ASIC voltages due to the plurality of ASICs sharing one power supply. In such cases, ASIC voltage may be determined by the overall voltage for a board containing the ASICs and/or the impedance of the ASICs. It is also impossible to directly set a suitable frequency for all ASICs due to the fact that the ASICs' performance and power behavior are different and influence each other. Accordingly, while it may not be possible to exactly achieve a target pass rate (e.g., 97.5% from the example above) target pass rate for every ASIC, the system can limit the pass rate to a narrow range such that the average pass rate deviation from the ideal target rate (e.g., 97.5%) is not causing significant performance degradation. This adaptive PnP tuning solution involves tuning the overall throughput to achieve target performance, where a single ASIC's pass rate is within a suitable range of the target rate (e.g., 97.5%+/−1%).

In some embodiments, a target die temperature may be selected (e.g., according to a single ASIC bench result involving scanning different die temperatures in a chamber with fixed frequency and voltage) to achieve the best power efficiency with a target throughput. In some embodiments, for example, the target die temperature may be 55° C.

In some embodiments, it may not be possible to control the single ASIC's die temperature by adjusting the speed of the fan(s) cooling the ASICs (e.g., fan 115 in FIG. 1). Instead, the ASICs' average die temperature may be used for thermal tuning. In some embodiments, thermal tuning allows the ASICs' average die temperature to fluctuate in a narrow range (e.g., 55° C.+/−2° C.), which can reduce the fan speed adjust frequency to increase the fan's life cycle.

The adaptive PnP tuning solution provides an adaptive method to tune ASIC frequency and adjust board voltage step by step based on ASIC pass rate. Increasing one ASIC's frequency will provide a lower impedance and the current stack voltage will decrease, then another stack's voltage will increase. This provides an opportunity for the other stack's ASIC to increase frequency due to high voltage to achieve a high pass rate, and all the ASICs' voltages and frequencies can be autofit and balanced through sever rounds of frequency and voltage tuning.

FIG. 2B illustrates a more detailed flow diagram based on the example shown in FIG. 2A. In this example, the process begins with an initialization after the system is powered on (PnP Tuning Start). The initialization sets: a target die temperature (e.g., 55° C.) for thermal tuning, a default board voltage (e.g, 8875 mV), a target pass rate (e.g., 97.5%), a target throughput (e.g., 40 TH/s) for ASIC frequency coarse tuning and board voltage tuning, and a pass rate range (97.5%+/−1%) for ASIC frequency fine tuning. It should be noted that these values are exemplary only, and alternate embodiments of the present disclosure may utilize different parameter values based on the application of the multi-ASIC system and associated bench test results.

In FIG. 2B, the “Set Target Thermal” step in conjunction with Dynamic Fan Speed Control 205 is used to keep the board average die temperature converged at or near the target die temperature (e.g., 55° C. in the present example). By adjusting the fan speed, the system can help ensure that the ASICs will operate efficiently and help reduce current leakage to improve power efficiency.

A PID algorithm may be used for dynamic fan speed control. In such cases, the PID algorithm may utilize an input comprising the average die temperature for the plurality of ASICs, and analyze a gap between average die temperature and target die temperature to calculate a new fan speed. For example, if the average die temperature is higher than the target die temperature, the system can increase the fan speed, otherwise the system may decrease or maintain the fan speed. After setting a new fan speed, the system may wait a predetermined period of time to let the ASIC die temperature stabilize, and continue to run PID algorithm until the average die temperature is converged to (or near) the target die temperature. For example, this process may allow the average die temperature to fluctuate in a narrow range (e.g., 55° C.+/−2° C.), which can also help reduce the fan speed adjust frequency to increase the fan's life cycle.

In FIG. 2B, the steps in section 210 involve ASIC frequency coarse tuning as introduced above with reference to FIG. 2A. In these steps, ASIC coarse frequency tuning is used to adjust (e.g., increase) the overall ASIC frequency to meet the target throughput requirement using a frequency adjust step (e.g., 25 MHz).

In this example, the system may increase the frequency of all ASICs in the plurality of ASICs by 25 MHz, then calculate the ASIC pass rate for a known job processed by the ASICs. If the ASIC pass rate is less than the target pass rate, it indicates the ASIC can't efficiently work at the current frequency, and the system may reset the ASIC frequency to the previous frequency (e.g., reduce the frequency 25 MHz).

Continuing this example, the system may calculate the overall throughput for the plurality of ASICs (e.g., for a board populated by the ASICs). If the determined throughput is higher than the target throughput, the system may exit ASIC frequency tuning and begin board voltage tuning, described below. Otherwise, the system may determine an increased average frequency for the plurality of ASICs. If the average frequency is less than a predetermined threshold (e.g., 6.25 MHz), the system may determine that less than 25% of the ASICs can successfully increase frequency, and the system needs to increase board voltage to allow more ASICs to increase their frequency. In some embodiments, for example, the board voltage may be increased by 40 mV. Ibis process for ASIC coarse frequency tuning may be repeated until the plurality of ASICs achieve the target throughput, then the ASIC frequency coarse tuning process may conclude.

In FIG. 2B, the steps in section 220 relate to board voltage tuning, which is used to adjust (e.g., decrease) the voltage supplied to the plurality of ASICs (e.g., the power supplied to a board populated by the plurality of ASICs) to improve power efficiency. Continuing the example from above, the voltage adjust step for the board voltage tuning may be 40 mV, which corresponds to a DAC resolution.

As illustrated by the steps in section 220 of FIG. 2B, the board voltage is decreased by the determined adjust step value (e.g., 40 mV in the present example), and an average pass rate for the ASICs on the board (board pass rate) associated with a known job assigned to the plurality ASICs is determined. If the board pass rate is less than the target pass rate, the system may determine ASICs can't efficiently work on the current voltage, and the system may reset the board voltage to the previous voltage (e.g., increase the voltage by 40 mV) and exit the board voltage tuning process. Otherwise, the system may repeat the steps in section 320 until the board pass rate is less than the target pass rate, then reset the board voltage to the previous voltage and conclude the board voltage tuning process.

The steps in section 230 in FIG. 2B relate to ASIC frequency fine tuning as introduced above in FIG. 2A. The ASIC frequency fine tuning process is used to keep all ASIC frequencies in range of the target pass rate (e.g., 97.5%+/−1%), which helps improve power efficiency. The frequency adjust step may be smaller than that used in the ASIC coarse frequency tuning process. For example, the frequency adjust step for fine tuning may be 8.33 MHz to correspond to an ASIC frequency resolution.

As illustrated in Section 230 of FIG. 2B, If the ASIC pass rate is higher than the high end of target pass rate range (e.g., 98.5% in the current example), the system may determine that the ASICs can efficiently work at a higher frequency, and increase ASIC frequency by 8.33 MHz. If, on the other hand, the ASIC pass rate is lower than the low end of the target pass rate range (e.g., 96.5% in the current example) the system may determine that the ASICs need to work at a lower frequency to improve power efficiency, and decrease the ASIC frequency by 8.33 MHz.

The system may calculate the ASIC pass rate associated with a known job assigned to the ASICs, and if the ASIC pass rate is within the predetermined range of the target pass rate (e.g., 97.5%+/−1%) the system may conclude the ASIC frequency fine tuning process end the PnP tuning process. As described above with reference to FIG. 2A, the system may optionally “Store PnP Tuning Results” into (e.g., flash) memory. The tuning results may include the ASICs' frequency and input voltage, which can be directly applied at the next reboot to help reduce boot time.

### ASIC Voltage Adjustment to Avoid Hardware Damage

As introduced above, the system in FIG. 1 may be implemented as part of a cryptocurrency mining system or (e.g., for any suitable form of blockchain technology) as well as for other multi-ASIC applications. In some embodiments, for example, the system may include one control board, four hash boards and a power module that are assembled in one chassis.

In such embodiments, the hash boards are populated with many ASICs to support the system's capability (e.g., for mining/hash computing). A microcontroller (MCU) is provided per hash board to monitor and control board voltage by communicating to the control system-on-chip (SoC) on the control board. In some embodiments, the design for many-ASICs on one hash board is a power stacking model where a few ASICs are connected in parallel to form a “stack.” Multiple stacks are then connected in series and connected to a single power input, such that multiple stacks share the same power voltage.

In one example, one hash board has 25 stacks in series, each stack has 3 ASICs in parallel, totaling 75 ASICs. Furthermore, one ASIC may include a plurality of engines (e.g., 129 engines in one example). In some embodiments, the engine is an independent processing unit configured to run a cryptocurrency hash algorithm (such as bitcoin SHA256), which takes an arbitrary-length data input called a “job” and produces a fixed-length deterministic result.

In such embodiments, each engine needs to work within a suitable voltage range. Higher voltages may cause the engine to be damaged and the engine may not be able to function at lower voltages. The engine initial status is “idle,” and when assigning a job to an engine, the engine status will change to “working” and its impedance will decrease. However, it may be difficult or impossible to assign jobs to all engines at the same time due to bandwidth limitations associated with the communication interface 114 (e.g., UART). Additionally, the ASICs' impedance is changed as the number of working engines changes, and the more engines in a working state, the lower the impedance.

Accordingly, the ASICs will impact each other since all of them share one power supply to achieve better power efficiency and reduce design complexity and manufacturing cost. Furthermore, even if the number of working engines in the stacks are the same, voltage stacks might have different voltage due to leakage variations of the ASICs caused by silicon manufacturing limitations and imperfections. It is therefore difficult for multi-ASIC systems to provide a power-on solution to keep the stack voltage balanced in the engines power on sequence.

Previous solutions to this issue include attempting to set the voltage high enough that all the ASICs will be function correctly, or providing a separate power supply for every ASIC. However, an attempt to set the voltage high enough that all the engines are functioning correctly may inadvertently cause damage to the engines due to imbalanced high voltages and/or result in peak current where the power supply will auto-protect itself by dropping the supplied power. Providing separate power supplies for every ASIC, on the other hand, will drastically add to the cost of the system, and the power efficiency will be relatively low due to the voltage converting cost. Embodiments of the present disclosure can provide voltage adjustment for multi-ASIC systems to address these and other issues.

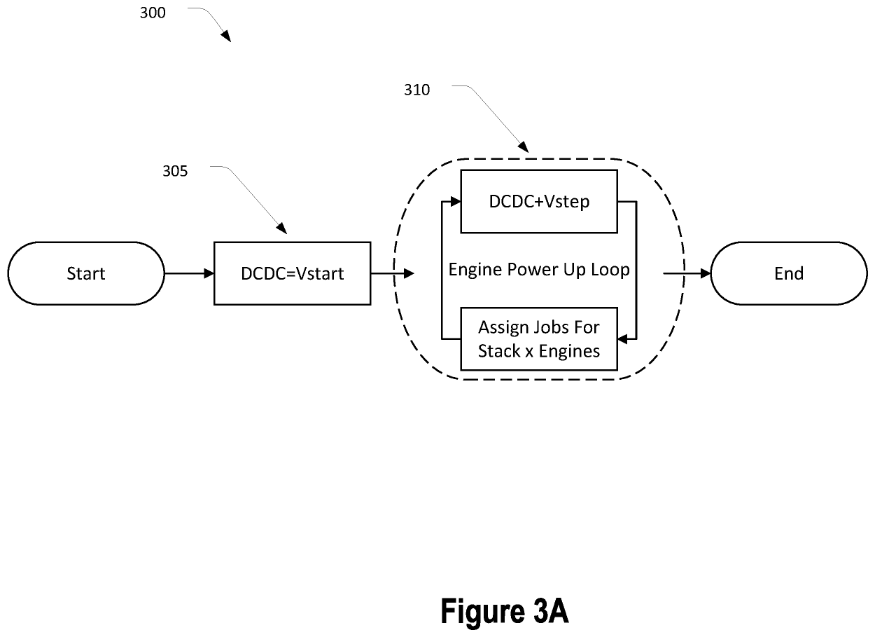

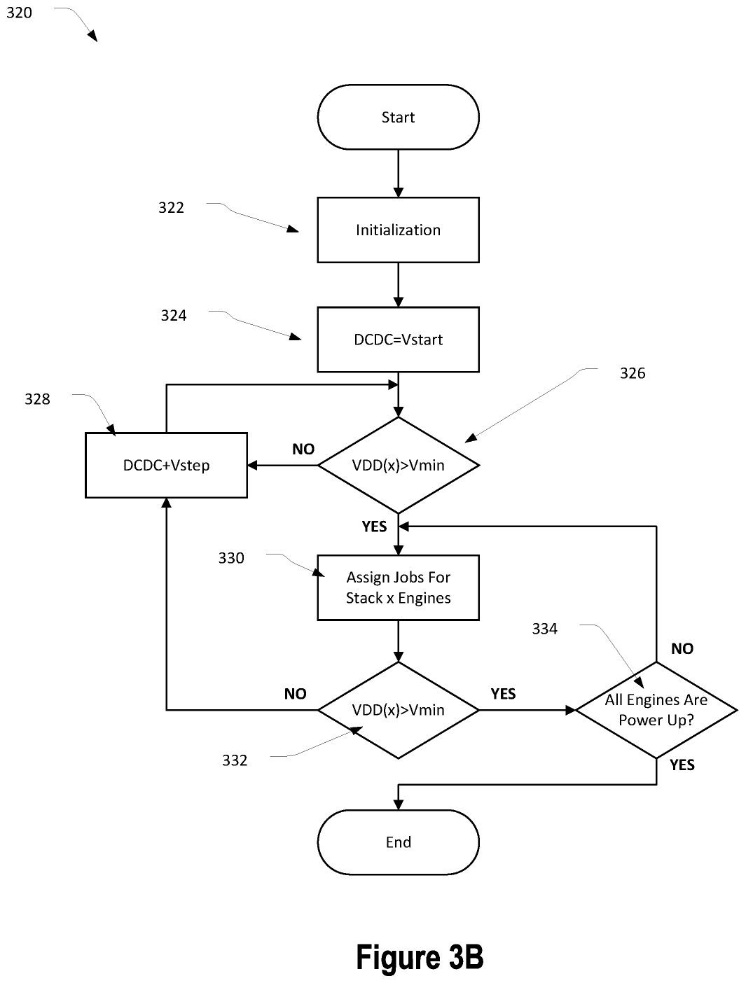

In some embodiments, for example, instead of setting the board voltage to a high value in one shot, the system may ramp up the power voltage step-by-step to accommodate many ASICs and many engines within the multi-ASIC system powering on. An example of a process flow diagram is illustrated in FIG. 3A. In this example process 300 includes, at 305, starting with an initial (relatively-low) board voltage supply (Vstart). At 310, the process includes an engine power-up loop where the voltage supplied to the plurality of ASICs is gradually increased until a voltage of a stack meets the minimal required voltage. In some embodiments the minimum required voltage may be equal to or slightly greater than the engine's normal operating voltage.

Also within loop 310, the system assigns test jobs to some engines in the stack where the minimal required voltage was met in order to keep those engines in a working state. In some embodiments, the test job run time may be selected to run sufficiently long to ensure the engines won't idle during power on sequence.

This loop 310 can be repeated for all engines in the stack. Once all engines are powered up, the test jobs can be flushed and the system can assign real jobs (e.g., for cryptocurrency mining) for the engines to perform.

Embodiments of the present disclosure provide a number of advantages compared with other solutions. For example, by starting with a relatively low board voltage and step-by-step ramping up the voltage helps to avoid potential hardware damage due to imbalanced high voltage or power supply protection due to high current. In addition, the system can increase the number of engines powered up in each ramp up round, which can reduce the overall system power on time (e.g., from around 10 minutes to less than 2 minutes). Power on time reduction not only improves the user experience, but also leave more time to perform the task(s) assigned to the multi-ASIC system (e.g., mining cryptocurrency).

In some embodiments, powering on the engines will cause the stack voltage to decrease, therefore the system may choose the stack for which the voltage is higher than the normal operating engine voltage to help avoid the engines being under-voltaged.

In cryptocurrency mining applications, a quick power-on feature is highly desirable. Conventional systems usually take about ten to twenty minutes to power on before mining can start. The power on techniques described for embodiments described herein, by contrast, may help the mining system to power on and start mining in 2 minutes or less. This feature may be referred to herein using terms such as: fast power on, instant power on, voltage stacking, crypto mining, test job, or voltage ramp up.

With reference to FIG. 3B, aspects of the fast power on techniques are further described below. Although specific values are used to demonstrate example implementations, it will be apparent that other values may be used in accordance with various embodiments herein.

In FIG. 3B, process 320 for adjusting the voltage supplied to a plurality of ASICs includes, at 322, an initialization step where an engine typical operating voltage is 355 mV, and the minimal required voltage is set to 375 mV (higher than typical operating voltage) to make sure the engine can operate normally.

At 324, the start voltage (Vstart) is set (e.g., to 3000 mV in this example), to account for a typically-large voltage variance between when no engine in a stack is working and when all the engines in the stack are working. The system may set the start voltage low enough to avoid damaging the engines of the stacks due to unbalanced voltage.

The process 300 continues to loop through the stacks to find the highest voltage stack. At 326 the system determines whether the stack voltage is lower than the minimal required voltage (e.g., 375 mV in the current example), and (if so) increase the board voltage by Vstep (e.g., 333 mV in this example) at 328 until there is a stack voltage that meets the minimal required voltage.

At 330, the system assigns relatively-long duration test jobs to engines in the selected stack. In some embodiments, the system may start by powering up a single engine and increase the number engines powered up by one in each round of power ramp up. In some embodiments, a maximum number of powered up engines may be set (e.g., to 10) to help avoid working engines being under-voltage.

At 332, the system checks again to determine whether the stack voltage is lower than the minimum required voltage, and looping back to 328 to increase the board voltage by Vstep if so. At 334, the system determines whether all engines have been powered up, and looping back to step 330 if not. If so, the overall stack voltage for the stacks will be changed, and the system may sleep a short time (e.g., 100 ms) to allow the stacks voltage to stabilize. With the power-on sequence concluded, the system may flush the test jobs and assign real jobs (e.g., for cryptocurrency mining) from a pool to the multi-ASIC system.

FIG. 4 illustrates a device 400 to implement various embodiments herein. The device 400 may be a smart device, computer system, system-on-chip, or other suitable device. For example, in some embodiments, device 400 represents an appropriate computing device, such as a computing tablet, a mobile phone or smart-phone, a laptop, a desktop, an Internet-of-Things (IoT) device, a server, a wearable device, a set-top box, a wireless-enabled e-reader, or the like. In some embodiments, device 400 may include or implement the components of the controller 110 in the multi-ASIC system 100 described above with reference to FIG. 1

It will be understood that certain components are shown generally, and not all components of such a device are shown in device 400. Additionally, it is noted that elements of FIG. 4 having the same reference numbers or names as the elements of any other figure may operate or function in any manner similar to that described, but are not limited as such.

In an example, the device 400 comprises an SoC (System-on-Chip) 401. An example boundary of the SoC 401 is illustrated using dotted lines in FIG. 4 with some example components being illustrated to be included within SoC 401—however, SoC 401 may include any appropriate components of device 400.

In some embodiments, device 400 includes processor 404. Processor 404 can include one or more physical devices, such as microprocessors, application processors, microcontrollers, programmable logic devices, processing cores, or other processing means. The processing operations performed by processor 404 include the execution of an operating platform or operating system on which applications and/or device functions are executed. The processing operations include operations related to I/O (input/output) with a human user or with other devices, operations related to power management, operations related to connecting computing device 400 to another device, and/or the like. The processing operations may also include operations related to audio I/O and/or display I/O.

In some embodiments, processor 404 includes multiple processing cores (also referred to as cores) 408a, 408b, 408c. Although merely three cores 408a, 408b, 408c are illustrated in FIG. 4, processor 404 may include any other appropriate number of processing cores, e.g., tens, or even hundreds of processing cores. Processor cores 408a, 408b, 408c may be implemented on a single integrated circuit (IC) chip. Moreover, the chip may include one or more shared and/or private caches, buses or interconnections, graphics and/or memory controllers, or other components.

In some embodiments, processor 404 includes cache 406. In an example, sections of cache 406 may be dedicated to individual cores 408 (e.g., a first section of cache 406 dedicated to core 408a, a second section of cache 406 dedicated to core 408b, and so on). In an example, one or more sections of cache 406 may be shared among two or more of cores 408. Cache 406 may be split in different levels, e.g., level 1 (L1) cache, level 2 (L2) cache, level 3 (L3) cache, etc.

In some embodiments, processor core 404 may include a fetch unit to fetch instructions (including instructions with conditional branches) for execution by the core 404. The instructions may be fetched from any storage devices such as the memory 430. Processor core 404 may also include a decode unit to decode the fetched instruction. For example, the decode unit may decode the fetched instruction into a plurality of micro-operations. Processor core 404 may include a schedule unit to perform various operations associated with storing decoded instructions. For example, the schedule unit may hold data from the decode unit until the instructions are ready for dispatch, e.g., until all source values of a decoded instruction become available. In one embodiment, the schedule unit may schedule and/or issue (or dispatch) decoded instructions to an execution unit for execution.

The execution unit may execute the dispatched instructions after they are decoded (e.g., by the decode unit) and dispatched (e.g., by the schedule unit). In an embodiment, the execution unit may include more than one execution unit (such as an imaging computational unit, a graphics computational unit, a general-purpose computational unit, etc.). The execution unit may also perform various arithmetic operations such as addition, subtraction, multiplication, and/or division, and may include one or more an arithmetic logic units (ALUs). In an embodiment, a co-processor (not shown) may perform various arithmetic operations in conjunction with the execution unit.

Further, execution unit may execute instructions out-of-order. Hence, processor core 404 may be an out-of-order processor core in one embodiment. Processor core 404 may also include a retirement unit. The retirement unit may retire executed instructions after they are committed. In an embodiment, retirement of the executed instructions may result in processor state being committed from the execution of the instructions, physical registers used by the instructions being de-allocated, etc. Processor core 404 may also include a bus unit to enable communication between components of processor core 404 and other components via one or more buses. Processor core 404 may also include one or more registers to store data accessed by various components of the core 404 (such as values related to assigned app priorities and/or sub-system states (modes) association.

In some embodiments, device 400 comprises connectivity circuitries 431. For example, connectivity circuitries 431 includes hardware devices (e.g., wireless and/or wired connectors and communication hardware) and/or software components (e.g., drivers, protocol stacks), e.g., to enable device 400 to communicate with external devices. Device 400 may be separate from the external devices, such as other computing devices, wireless access points or base stations, etc.

In an example, connectivity circuitries 431 may include multiple different types of connectivity. To generalize, the connectivity circuitries 431 may include cellular connectivity circuitries, wireless connectivity circuitries, etc. Cellular connectivity circuitries of connectivity circuitries 431 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, 3rd Generation Partnership Project (3GPP) Universal Mobile Telecommunications Systems (UMTS) system or variations or derivatives, 3GPP Long-Term Evolution (LTE) system or variations or derivatives, 3GPP LTE-Advanced (LTE-A) system or variations or derivatives, Fifth Generation (5G) wireless system or variations or derivatives, 5G mobile networks system or variations or derivatives, 5G New Radio (NR) system or variations or derivatives, or other cellular service standards. Wireless connectivity circuitries (or wireless interface) of the connectivity circuitries 431 refers to wireless connectivity that is not cellular, and can include personal area networks (such as Bluetooth, Near Field, etc.), local area networks (such as Wi-Fi), and/or wide area networks (such as WiMax), and/or other wireless communication. In an example, connectivity circuitries 431 may include a network interface, such as a wired or wireless interface, e.g., so that a system embodiment may be incorporated into a wireless device, for example, a cell phone or personal digital assistant.

In some embodiments, device 400 comprises control hub 432, which represents hardware devices and/or software components related to interaction with one or more I/O devices. For example, processor 404 may communicate with one or more of display 422, one or more peripheral devices 424, storage devices 428, one or more other external devices 429, etc., via control hub 432. Control hub 432 may be a chipset, a Platform Control Hub (PCH), and/or the like.

For example, control hub 432 illustrates one or more connection points for additional devices that connect to device 400, e.g., through which a user might interact with the system. For example, devices (e.g., devices 429) that can be attached to device 400 include microphone devices, speaker or stereo systems, audio devices, video systems or other display devices, keyboard or keypad devices, or other I/O devices for use with specific applications such as card readers or other devices.

As mentioned above, control hub 432 can interact with audio devices, display 422, etc. For example, input through a microphone or other audio device can provide input or commands for one or more applications or functions of device 400. Additionally, audio output can be provided instead of, or in addition to display output. In another example, if display 422 includes a touch screen, display 422 also acts as an input device, which can be at least partially managed by control hub 432. There can also be additional buttons or switches on computing device 400 to provide I/O functions managed by control hub 432. In one embodiment, control hub 432 manages devices such as accelerometers, cameras, light sensors or other environmental sensors, or other hardware that can be included in device 400. The input can be part of direct user interaction, as well as providing environmental input to the system to influence its operations (such as filtering for noise, adjusting displays for brightness detection, applying a flash for a camera, or other features).

In some embodiments, control hub 432 may couple to various devices using any appropriate communication protocol, e.g., PCIe (Peripheral Component Interconnect Express), USB (Universal Serial Bus), Thunderbolt, High Definition Multimedia Interface (HDMI), Firewire, etc.

In some embodiments, display 422 represents hardware (e.g., display devices) and software (e.g., drivers) components that provide a visual and/or tactile display for a user to interact with device 400. Display 422 may include a display interface, a display screen, and/or hardware device used to provide a display to a user. In some embodiments, display 422 includes a touch screen (or touch pad) device that provides both output and input to a user. In an example, display 422 may communicate directly with the processor 404. Display 422 can be one or more of an internal display device, as in a mobile electronic device or a laptop device or an external display device attached via a display interface (e.g., DisplayPort, etc.). In one embodiment display 422 can be a head mounted display (HMD) such as a stereoscopic display device for use in virtual reality (VR) applications or augmented reality (AR) applications.

In some embodiments, and although not illustrated in the figure, in addition to (or instead of) processor 404, device 400 may include Graphics Processing Unit (GPU) comprising one or more graphics processing cores, which may control one or more aspects of displaying contents on display 422.

Control hub 432 (or platform controller hub) may include hardware interfaces and connectors, as well as software components (e.g., drivers, protocol stacks) to make peripheral connections, e.g., to peripheral devices 424.

It will be understood that device 400 could both be a peripheral device to other computing devices, as well as have peripheral devices connected to it. Device 400 may have a “docking” connector to connect to other computing devices for purposes such as managing (e.g., downloading and/or uploading, changing, synchronizing) content on device 400. Additionally, a docking connector can allow device 400 to connect to certain peripherals that allow computing device 400 to control content output, for example, to audiovisual or other systems.

In addition to a proprietary docking connector or other proprietary connection hardware, device 400 can make peripheral connections via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

In some embodiments, connectivity circuitries 431 may be coupled to control hub 432, e.g., in addition to, or instead of, being coupled directly to the processor 404. In some embodiments, display 422 may be coupled to control hub 432, e.g., in addition to, or instead of, being coupled directly to processor 404.

In some embodiments, device 400 comprises memory 430 coupled to processor 404 via memory interface 434. Memory 430 includes memory devices for storing information in device 400, such as the memory/storage components 105 illustrated in FIG. 1.

In some embodiments, memory 430 includes apparatus to maintain stable clocking as described with reference to various embodiments. Memory can include nonvolatile (state does not change if power to the memory device is interrupted) and/or volatile (state is indeterminate if power to the memory device is interrupted) memory devices. Memory device 430 can be a dynamic random-access memory (DRAM) device, a static random-access memory (SRAM) device, flash memory device, phase-change memory device, or some other memory device having suitable performance to serve as process memory. In one embodiment, memory 430 can operate as system memory for device 400, to store data and instructions for use when the one or more processors 404 executes an application or process. Memory 430 can store application data, user data, music, photos, documents, or other data, as well as system data (whether long-term or temporary) related to the execution of the applications and functions of device 400.

Elements of various embodiments and examples are also provided as a machine-readable medium (e.g., memory 430) for storing the computer-executable instructions (e.g., instructions to implement any other processes discussed herein). The machine-readable medium (e.g., memory 430) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

In some embodiments, device 400 comprises temperature measurement circuitries 440, e.g., for measuring temperature of various components of device 400, such as the fan and temperature control component 112 in FIG. 1. In an example, temperature measurement circuitries 440 may be embedded, or coupled or attached to various components, whose temperature are to be measured and monitored. For example, temperature measurement circuitries 440 may measure temperature of (or within) one or more of cores 408a, 408b, 408c, voltage regulator 414, memory 430, a mother-board of SoC 401, and/or any appropriate component of device 400. In some embodiments, temperature measurement circuitries 440 include a low power hybrid reverse (LPHR) bandgap reference (BGR) and digital temperature sensor (DTS), which utilizes subthreshold metal oxide semiconductor (MOS) transistor and the PNP parasitic Bi-polar Junction Transistor (BJT) device to form a reverse BGR that serves as the base for configurable BGR or DTS operating modes. The LPHR architecture uses low-cost MOS transistors and the standard parasitic PNP device. Based on a reverse bandgap voltage, the LPHR can work as a configurable BGR. By comparing the configurable BGR with the scaled base-emitter voltage, the circuit can also perform as a DTS with a linear transfer function with single-temperature trim for high accuracy. As further illustrated in FIG. 1, temperature measurement circuitries 440 may be coupled to one or more temperature control systems for controlling (heating or cooling) various components of device 400, such as the fan 115 in FIG. 1.

In some embodiments, device 400 comprises power measurement circuitries 442, e.g., for measuring power consumed by one or more components of the device 400. In an example, in addition to, or instead of, measuring power, the power measurement circuitries 442 may measure voltage and/or current. In an example, the power measurement circuitries 442 may be embedded, or coupled or attached to various components, whose power, voltage, and/or current consumption are to be measured and monitored. For example, power measurement circuitries 442 may measure power, current and/or voltage supplied by one or more voltage regulators 414, power supplied to SoC 401, power supplied to device 400, power consumed by processor 404 (or any other component) of device 400, etc. In some embodiments, power measurement circuitries 442 may be coupled to a power supply (such as power supply 130 in FIG. 1) to regulate power supplied to one or more components of device 400 (such as ASICS 125 in FIG. 1).

In some embodiments, device 400 comprises one or more voltage regulator circuitries, generally referred to as voltage regulator (VR) 414. VR 414 generates signals at appropriate voltage levels, which may be supplied to operate any appropriate components of the device 400. Merely as an example, VR 414 is illustrated to be supplying signals to processor 404 of device 400. In some embodiments, VR 414 receives one or more Voltage Identification (VID) signals, and generates the voltage signal at an appropriate level, based on the VID signals. Various type of VRs may be utilized for the VR 414. For example, VR 414 may include a “buck” VR, “boost” VR, a combination of buck and boost VRs, low dropout (LDO) regulators, switching DC-DC regulators, constant-on-time controller-based DC-DC regulator, etc. Buck VR is generally used in power delivery applications in which an input voltage needs to be transformed to an output voltage in a ratio that is smaller than unity. Boost VR is generally used in power delivery applications in which an input voltage needs to be transformed to an output voltage in a ratio that is larger than unity. In some embodiments, each processor core has its own VR, which is controlled by PCU 410a/b and/or PMIC 412. In some embodiments, each core has a network of distributed LDOs to provide efficient control for power management. The LDOs can be digital, analog, or a combination of digital or analog LDOs. In some embodiments, VR 414 includes current tracking apparatus to measure current through power supply rail(s).

In some embodiments, VR 414 includes a digital control scheme to manage states of a proportional-integral-derivative (PID) filter (also known as a digital Type-III compensator). The digital control scheme controls the integrator of the PID filter to implement non-linear control of saturating the duty cycle during which the proportional and derivative terms of the PID are set to 0 while the integrator and its internal states (previous values or memory) is set to a duty cycle that is the sum of the current nominal duty cycle plus a deltaD. The deltaD is the maximum duty cycle increment that is used to regulate a voltage regulator from ICCmin to ICCmax and is a configuration register that can be set post silicon. A state machine moves from a non-linear all ON state (which brings the output voltage Vout back to a regulation window) to an open loop duty cycle which maintains the output voltage slightly higher than the required reference voltage Vref. After a certain period in this state of open loop at the commanded duty cycle, the state machine then ramps down the open loop duty cycle value until the output voltage is close to the Vref commanded. As such, output chatter on the output supply from VR 414 is completely eliminated (or substantially eliminated) and there is merely a single undershoot transition which could lead to a guaranteed Vmin based on a comparator delay and the di/dt of the load with the available output decoupling capacitance.

In some embodiments, VR 414 includes a separate self-start controller, which is functional without fuse and/or trim information. The self-start controller protects VR 414 against large inrush currents and voltage overshoots, while being capable of following a variable VID (voltage identification) reference ramp imposed by the system. In some embodiments, the self-start controller uses a relaxation oscillator built into the controller to set the switching frequency of the buck converter. The oscillator can be initialized using either a clock or current reference to be close to a desired operating frequency. The output of VR 414 is coupled weakly to the oscillator to set the duty cycle for closed loop operation. The controller is naturally biased such that the output voltage is always slightly higher than the set point, eliminating the need for any process, voltage, and/or temperature (PVT) imposed trims.

In some embodiments, VR 414 includes a controlled current source or a parallel current source (PCS) to assist a DC-DC buck converter and to alleviate the stress on the C4 bumps while boosting the efficiency of the DC-DC converter at the high-load current scenarios. The PSC adds current to the output power supply rail, which is coupled to a load. In some embodiments, the PCS is activated to mitigate droop events due to high di/dt events on the output power supply rail. The PCS provides charge directly to the load (driving in parallel to the DC-DC converter) whenever the current supplied by the DC-DC converter is above a certain threshold level.

In some embodiments, device 400 comprises one or more clock generator circuitries, generally referred to as clock generator 416. Clock generator 416 generates clock signals at appropriate frequency levels, which may be supplied to any appropriate components of device 400. Merely as an example, clock generator 416 is illustrated to be supplying clock signals to processor 404 of device 400. In some embodiments, clock generator 416 receives one or more Frequency Identification (FID) signals, and generates the clock signals at an appropriate frequency, based on the FID signals.

In some embodiments, device 400 comprises battery 418 supplying power to various components of device 400. Merely as an example, battery 418 is illustrated to be supplying power to processor 404. Although not illustrated in the figures, device 400 may comprise a charging circuitry, e.g., to recharge the battery, based on Alternating Current (AC) power supply received from an AC adapter.

In some embodiments, the charging circuitry (e.g., 418) comprises a buck-boost converter. This buck-boost converter comprises DrMOS or DrGaN devices used in place of half-bridges for traditional buck-boost converters. Various embodiments here are described with reference to DrMOS. However, the embodiments are applicable to DrGaN. The DrMOS devices allow for better efficiency in power conversion due to reduced parasitic and optimized MOSFET packaging. Since the dead-time management is internal to the DrMOS, the dead-time management is more accurate than for traditional buck-boost converters leading to higher efficiency in conversion. Higher frequency of operation allows for smaller inductor size, which in turn reduces the z-height of the charger comprising the DrMOS based buck-boost converter. The buck-boost converter of various embodiments comprises dual-folded bootstrap for DrMOS devices. In some embodiments, in addition to the traditional bootstrap capacitors, folded bootstrap capacitors are added that cross-couple inductor nodes to the two sets of DrMOS switches.

In some embodiments, device 400 comprises Power Control Unit (PCU) 410 (also referred to as Power Management Unit (PMU), Power Management Controller (PMC), Power Unit (p-unit), etc.). In an example, some sections of PCU 410 may be implemented by one or more processing cores 408, and these sections of PCU 410 are symbolically illustrated using a dotted box and labelled PCU 410a. In an example, some other sections of PCU 410 may be implemented outside the processing cores 408, and these sections of PCU 410 are symbolically illustrated using a dotted box and labelled as PCU 410b. PCU 410 may implement various power management operations for device 400. PCU 410 may include hardware interfaces, hardware circuitries, connectors, registers, etc., as well as software components (e.g., drivers, protocol stacks), to implement various power management operations for device 400.

In various embodiments, PCU or PMU 410 is organized in a hierarchical manner forming a hierarchical power management (HPM). HPM of various embodiments builds a capability and infrastructure that allows for package level management for the platform, while still catering to islands of autonomy that might exist across the constituent die in the package. HPM does not assume a pre-determined mapping of physical partitions to domains. An HPM domain can be aligned with a function integrated inside a dielet, to a dielet boundary, to one or more dielets, to a companion die, or even a discrete CXL device. HPM addresses integration of multiple instances of the same die, mixed with proprietary functions or 3rd party functions integrated on the same die or separate die, and even accelerators connected via CXL (e.g., Flexbus) that may be inside the package, or in a discrete form factor.

HPM enables designers to meet the goals of scalability, modularity, and late binding. HPM also allows PMU functions that may already exist on other dice to be leveraged, instead of being disabled in the flat scheme. HPM enables management of any arbitrary collection of functions independent of their level of integration. HPM of various embodiments is scalable, modular, works with symmetric multi-chip processors (MCPs), and works with asymmetric MCPs. For example, HPM does not need a signal PM controller and package infrastructure to grow beyond reasonable scaling limits. HPM enables late addition of a die in a package without the need for change in the base die infrastructure. HPM addresses the need of disaggregated solutions having dies of different process technology nodes coupled in a single package. HPM also addresses the needs of companion die integration solutions-on and off package. Other technical effects will be evident from the various figures and embodiments.

In some embodiments, device 400 comprises Power Management Integrated Circuit (PMIC) 412, e.g., to implement various power management operations for device 400. In some embodiments, PMIC 412 is a Reconfigurable Power Management ICs (RPMICs) and/or an IMVP (Intel® Mobile Voltage Positioning). In an example, the PMIC is within an IC die separate from processor 404. The may implement various power management operations for device 400. PMIC 412 may include hardware interfaces, hardware circuitries, connectors, registers, etc., as well as software components (e.g., drivers, protocol stacks), to implement various power management operations for device 400.

In an example, device 400 comprises one or both PCU 410 or PMIC 412. In an example, any one of PCU 410 or PMIC 412 may be absent in device 400, and hence, these components are illustrated using dotted lines.

Various power management operations of device 400 may be performed by PCU 410, by PMIC 412, or by a combination of PCU 410 and PMIC 412. For example, PCU 410 and/or PMIC 412 may select a power state (e.g., P-state) for various components of device 400. For example, PCU 410 and/or PMIC 412 may select a power state (e.g., in accordance with the ACPI (Advanced Configuration and Power Interface) specification) for various components of device 400. Merely as an example, PCU 410 and/or PMIC 412 may cause various components of the device 400 to transition to a sleep state, to an active state, to an appropriate C state (e.g., C0 state, or another appropriate C state, in accordance with the ACPI specification), etc. In an example, PCU 410 and/or PMIC 412 may control a voltage output by VR 414 and/or a frequency of a clock signal output by the clock generator, e.g., by outputting the VID signal and/or the FID signal, respectively. In an example, PCU 410 and/or PMIC 412 may control battery power usage, charging of battery 418, and features related to power saving operation.

The clock generator 416 can comprise a phase locked loop (PLL), frequency locked loop (FLL), or any suitable clock source. In some embodiments, each core of processor 404 has its own clock source. As such, each core can operate at a frequency independent of the frequency of operation of the other core. In some embodiments, PCU 410 and/or PMIC 412 performs adaptive or dynamic frequency scaling or adjustment. For example, clock frequency of a processor core can be increased if the core is not operating at its maximum power consumption threshold or limit. In some embodiments, PCU 410 and/or PMIC 412 determines the operating condition of each core of a processor, and opportunistically adjusts frequency and/or power supply voltage of that core without the core clocking source (e.g., PLL of that core) losing lock when the PCU 410 and/or PMIC 412 determines that the core is operating below a target performance level. For example, if a core is drawing current from a power supply rail less than a total current allocated for that core or processor 404, then PCU 410 and/or PMIC 412 can temporality increase the power draw for that core or processor 404 (e.g., by increasing clock frequency and/or power supply voltage level) so that the core or processor 404 can perform at higher performance level. As such, voltage and/or frequency can be increased temporality for processor 404 without violating product reliability.

In an example, PCU 410 and/or PMIC 412 may perform power management operations, e.g., based at least in part on receiving measurements from power measurement circuitries 442, temperature measurement circuitries 440, charge level of battery 418, and/or any other appropriate information that may be used for power management. To that end, PMIC 412 is communicatively coupled to one or more sensors to sense/detect various values/variations in one or more factors having an effect on power/thermal behavior of the system/platform. Examples of the one or more factors include electrical current, voltage droop, temperature, operating frequency, operating voltage, power consumption, inter-core communication activity, etc. One or more of these sensors may be provided in physical proximity (and/or thermal contact/coupling) with one or more components or logic/IP blocks of a computing system. Additionally, sensor(s) may be directly coupled to PCU 410 and/or PMIC 412 in at least one embodiment to allow PCU 410 and/or PMIC 412 to manage processor core energy at least in part based on value(s) detected by one or more of the sensors.

Also illustrated is an example software stack of device 400 (although not all elements of the software stack are illustrated). Merely as an example, processors 404 may execute application programs 450, Operating System 452, one or more Power Management (PM) specific application programs (e.g., generically referred to as PM applications 458), and/or the like. PM applications 458 may also be executed by the PCU 410 and/or PMIC 412. OS 452 may also include one or more PM applications 456a, 456b, 456c. The OS 452 may also include various drivers 454a, 454b, 454c, etc., some of which may be specific for power management purposes. In some embodiments, device 400 may further comprise a Basic Input/output System (BIOS) 420. BIOS 420 may communicate with OS 452 (e.g., via one or more drivers 454), communicate with processors 404, etc.

For example, one or more of PM applications 458, 456, drivers 454, BIOS 420, etc. may be used to implement power management specific tasks, e.g., to control voltage and/or frequency of various components of device 400, to control wake-up state, sleep state, and/or any other appropriate power state of various components of device 400, control battery power usage, charging of the battery 418, features related to power saving operation, etc.

In some embodiments, battery 418 is a Li-metal battery with a pressure chamber to allow uniform pressure on a battery. The pressure chamber is supported by metal plates (such as pressure equalization plate) used to give uniform pressure to the battery. The pressure chamber may include pressured gas, elastic material, spring plate, etc. The outer skin of the pressure chamber is free to bow, restrained at its edges by (metal) skin, but still exerts a uniform pressure on the plate that is compressing the battery cell. The pressure chamber gives uniform pressure to battery, which is used to enable high-energy density battery with, for example, 20% more battery life.

In some embodiments, pCode executing on PCU 410a/b has a capability to enable extra compute and telemetries resources for the runtime support of the pCode. Here pCode refers to a firmware executed by PCU 410a/b to manage performance of the 401. For example, pCode may set frequencies and appropriate voltages for the processor. Part of the pCode are accessible via OS 452. In various embodiments, mechanisms and methods are provided that dynamically change an Energy Performance Preference (EPP) value based on workloads, user behavior, and/or system conditions. There may be a well-defined interface between OS 452 and the pCode. The interface may allow or facilitate the software configuration of several parameters and/or may provide hints to the pCode. As an example, an EPP parameter may inform a pCode algorithm as to whether performance or battery life is more important.

This support may be done as well by the OS 452 by including machine-learning support as part of OS 452 and either tuning the EPP value that the OS hints to the hardware (e.g., various components of SoC 401) by machine-learning prediction, or by delivering the machine-learning prediction to the pCode in a manner similar to that done by a Dynamic Tuning Technology (DTT) driver. In this model, OS 452 may have visibility to the same set of telemetries as are available to a DTT. As a result of a DTT machine-learning hint setting, pCode may tune its internal algorithms to achieve optimal power and performance results following the machine-learning prediction of activation type. The pCode as example may increase the responsibility for the processor utilization change to enable fast response for user activity, or may increase the bias for energy saving either by reducing the responsibility for the processor utilization or by saving more power and increasing the performance lost by tuning the energy saving optimization. This approach may facilitate saving more battery life in case the types of activities enabled lose some performance level over what the system can enable. The pCode may include an algorithm for dynamic EPP that may take the two inputs, one from OS 452 and the other from software such as DT, and may selectively choose to provide higher performance and/or responsiveness. As part of this method, the pCode may enable in the DTT an option to tune its reaction for the DT for different types of activity.

In some embodiments, pCode improves the performance of the SoC in battery mode. In some embodiments, pCode allows drastically higher SoC peak power limit levels (and thus higher Turbo performance) in battery mode. In some embodiments, pCode implements power throttling and is part of Intel's Dynamic Tuning Technology (DTT). In various embodiments, the peak power limit is referred to PL4. However, the embodiments are applicable to other peak power limits. In some embodiments, pCode sets the Vth threshold voltage (the voltage level at which the platform will throttle the SoC) in such a way as to prevent the system from unexpected shutdown (or black screening). In some embodiments, pCode calculates the Psoc,pk SoC Peak Power Limit (e.g., PL4), according to the threshold voltage (Vth). These are two dependent parameters, if one is set, the other can be calculated. pCode is used to optimally set one parameter (Vth) based on the system parameters, and the history of the operation. In some embodiments, pCode provides a scheme to dynamically calculate the throttling level (Psoc,th) based on the available battery power (which changes slowly) and set the SoC throttling peak power (Psoc,th). In some embodiments, pCode decides the frequencies and voltages based on Psoc,th. In this case, throttling events have less negative effect on the SoC performance. Various embodiments provide a scheme which allows maximum performance (Pmax) framework to operate.

In some embodiments, VR 414 includes a current sensor to sense and/or measure current through a high-side switch of VR 414. In some embodiments the current sensor uses an amplifier with capacitively coupled inputs in feedback to sense the input offset of the amplifier, which can be compensated for during measurement. In some embodiments, the amplifier with capacitively coupled inputs in feedback is used to operate the amplifier in a region where the input common-mode specifications are relaxed, so that the feedback loop gain and/or bandwidth is higher. In some embodiments, the amplifier with capacitively coupled inputs in feedback is used to operate the sensor from the converter input voltage by employing high-PSRR (power supply rejection ratio) regulators to create a local, clean supply voltage, causing less disruption to the power grid in the switch area. In some embodiments, a variant of the design can be used to sample the difference between the input voltage and the controller supply, and recreate that between the drain voltages of the power and replica switches. This allows the sensor to not be exposed to the power supply voltage. In some embodiments, the amplifier with capacitively coupled inputs in feedback is used to compensate for power delivery network related (PDN-related) changes in the input voltage during current sensing.

### Example Procedures

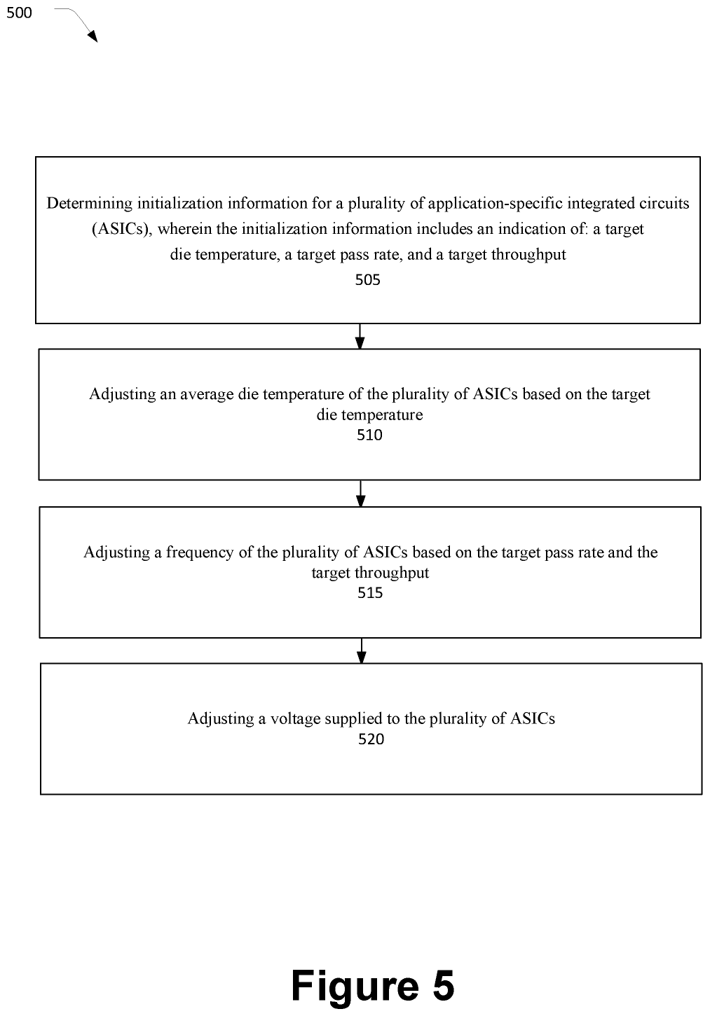

In some embodiments, the electronic device(s), system(s), chip(s) or component(s), or portions or implementations thereof, of FIG. 1 or 4, or some other figure herein, may be configured to perform one or more processes, techniques, or methods as described herein, or portions thereof. One such process is depicted in FIG. 5. In this example, the process 500 includes, at 505, determining initialization information for a plurality of application-specific integrated circuits (ASICs), wherein the initialization information includes an indication of: a target die temperature, a target pass rate, and a target throughput. The process further includes, at 510, adjusting an average die temperature of the plurality of ASICs based on the target die temperature. The process further includes, at 515, adjusting a frequency of the plurality of ASICs based on the target pass rate and the target throughput. The process further includes, at 520, adjusting a voltage supplied to the plurality of ASICs.

### EXAMPLES

Some non-limiting examples of various embodiments are presented below.

Example 1 is a device comprising:
a plurality of application specific integrated circuits (ASICs); and
PnP tuning circuitry to tune devices of the ASICs.

Example 2 is the device of example 1, wherein the PnP tuning circuitry is to perform ASIC coarse frequency tuning, board voltage tuning, and ASIC fine frequency tuning.

Example 3 is the device of example 2, wherein the board voltage tuning is performed after the ASIC coarse frequency tuning and before the ASIC fine frequency tuning.

Example 4 is the device of any of examples 1-3, wherein the plurality of ASICs are included in a HASH board of a bitcoin mining system.

Example X1 includes an apparatus comprising:

memory to store initialization information for a plurality of application-specific integrated circuits (ASICs); and

processing circuitry, coupled with the memory, to:
retrieve the initialization information from the memory, wherein the initialization information includes an indication of: a target die temperature, a target pass rate, and a target throughput;
adjust an average die temperature of the plurality of ASICs based on the target die temperature;
adjust a frequency of the plurality of ASICs based on the target pass rate and the target throughput; and
adjust a voltage supplied to the plurality of ASICs.

Example X2 includes the apparatus of example X1 or some other example herein, wherein adjusting the average die temperature of the plurality of ASICs includes dynamically adjusting a speed of one or more fans.

Example X3 includes the apparatus of example X1 or some other example herein, wherein adjusting the frequency of the plurality of ASICs includes performing a coarse frequency tuning procedure, and wherein the processing circuitry is further to perform a fine frequency tuning procedure on the plurality of ASICs subsequent to the coarse frequency tuning procedure.

Example X4 includes the apparatus of example X3 or some other example herein, wherein the coarse frequency tuning procedure includes adjusting the frequency of the plurality of ASICs by a first adjustment step, and wherein the fine frequency tuning procedure includes adjusting the frequency of the plurality of ASICs by a second adjustment step that is less than the first adjustment step.

Example X5 includes the apparatus of example X3 or some other example herein, wherein the coarse frequency tuning procedure includes determining a pass rate associated with a known job for an ASIC from the plurality of ASICs, and adjusting the frequency of the plurality of ASICs based on a comparison of the determined pass rate to the target pass rate.

Example X6 includes the apparatus of example X3 or some other example herein, wherein the coarse frequency tuning procedure includes:

determining that an overall throughput for the plurality of ASICs is lower than the target throughput; and

determining a frequency adjustment value to achieve the target throughput.

Example X7 includes the apparatus of example X6 or some other example herein, wherein the determined frequency adjustment value is lower than the second adjust step, and wherein the processing circuitry is further to increase the voltage supplied to the plurality of ASICs to achieve the target throughput.

Example X8 includes the apparatus of any of examples X1-X7 or some other example herein, wherein adjusting the voltage supplied to the plurality of ASICs includes determining an average pass rate associated with a known job for the plurality of ASICs and adjusting the voltage supplied to the plurality of ASICs based on a comparison of the determined average pass rate to the target pass rate.

Example X9 includes the apparatus of example X1 or some other example herein, wherein adjusting the voltage supplied to the plurality of ASICs includes increasing the voltage supplied to the plurality of ASICs until a voltage associated with a stack of ASICS connected in parallel meets a minimum predetermined voltage.

Example X10 includes the apparatus of example X9 or some other example herein, wherein adjusting the voltage supplied to the plurality of ASICs includes assigning respective test jobs to a subset of ASIC engines in the stack to prevent the subset of ASIC engines from idling subsequent to the voltage associated with the stack meeting the minimum predetermined voltage.

Example X11 includes the apparatus of example X9 or some other example herein, wherein the voltage supplied to the plurality of ASICs is initially about 3000 mV, and wherein the voltage supplied to the plurality of ASICs is increased in increments of about 333 mV.

Example X12 includes the apparatus of example X9 or some other example herein, wherein the minimum predetermined voltage is about 375 mV.

Example X13 includes the apparatus of any one of examples X1-X12 or some other example herein, wherein the apparatus comprises a controller coupled to the plurality of ASICs via a communications interface.

Example X14 includes one or more computer-readable media storing instructions that, when executed by one or more processors, cause a controller to:

determine initialization information for a plurality of application-specific integrated circuits (ASICs), wherein the initialization information includes an indication of: a target die temperature, a target pass rate, and a target throughput;

adjust an average die temperature of the plurality of ASICs based on the target die temperature;

adjust a frequency of the plurality of ASICs based on the target pass rate and the target throughput; and

adjust a voltage supplied to the plurality of ASICs.

Example X15 includes the one or more computer-readable media of example X14 or some other example herein, wherein adjusting the average die temperature of the plurality of ASICs includes dynamically adjusting a speed of one or more fans.

Example X16 includes the one or more computer-readable media of example X14 or some other example herein, wherein adjusting the frequency of the plurality of ASICs includes performing a coarse frequency tuning procedure, and wherein the processing circuitry is further to perform a fine frequency tuning procedure on the plurality of ASICs subsequent to the coarse frequency tuning procedure.

Example X17 includes the one or more computer-readable media of example X16 or some other example herein, wherein the coarse frequency tuning procedure includes adjusting the frequency of the plurality of ASICs by a first adjustment step, and wherein the fine frequency tuning procedure includes adjusting the frequency of the plurality of ASICs by a second adjustment step that is less than the first adjustment step.

Example X18 includes the one or more computer-readable media of example X16 or some other example herein, wherein the coarse frequency tuning procedure includes determining a pass rate associated with a known job for an ASIC from the plurality of ASICs, and adjusting the frequency of the plurality of ASICs based on a comparison of the determined pass rate to the target pass rate.

Example X19 includes the one or more computer-readable media of example X16 or some other example herein, wherein the coarse frequency tuning procedure includes:

determining that an overall throughput for the plurality of ASICs is lower than the target throughput; and

determining a frequency adjustment value to achieve the target throughput.

Example X20 includes the one or more computer-readable media of example X19 or some other example herein, wherein the determined frequency adjustment value is lower than the second adjust step, and wherein the processing circuitry is further to increase the voltage supplied to the plurality of ASICs to achieve the target throughput.

Example X21 includes the one or more computer-readable media of any of examples X14-X20 or some other example herein, wherein adjusting the voltage supplied to the plurality of ASICs includes determining an average pass rate associated with a known job for the plurality of ASICs and adjusting the voltage supplied to the plurality of ASICs based on a comparison of the determined average pass rate to the target pass rate.

Example X22 includes the one or more computer-readable media of example X14 or some other example herein, wherein adjusting the voltage supplied to the plurality of ASICs includes increasing the voltage supplied to the plurality of ASICs until a voltage associated with a stack of ASICS connected in parallel meets a minimum predetermined voltage.

Example X23 includes the one or more computer-readable media of example X22 or some other example herein, wherein adjusting the voltage supplied to the plurality of ASICs includes assigning respective test jobs to a subset of ASIC engines in the stack to prevent the subset of ASIC engines from idling subsequent to the voltage associated with the stack meeting the minimum predetermined voltage.

Example X24 includes the one or more computer-readable media of example X22 or some other example herein, wherein the voltage supplied to the plurality of ASICs is initially about 3000 mV, and wherein the voltage supplied to the plurality of ASICs is increased in increments of about 333 mV.

Example X25 includes the one or more computer-readable media of example X22 or some other example herein, wherein the minimum predetermined voltage is about 375 mV.

Example X26 includes the one or more computer-readable media of any of examples X14-X25 or some other example herein, wherein the controller is coupled to the plurality of ASICs via a communications interface.

Example X27 includes a system on a chip (SoC) comprising:

one or more processors; and

memory coupled to the one or more processors and storing instructions that, when executed by the one or more processors, cause the SoC to:
determine initialization information for a plurality of application-specific integrated circuits (ASICs), wherein the initialization information includes an indication of: a target die temperature, a target pass rate, and a target throughput;
adjust an average die temperature of the plurality of ASICs based on the target die temperature;
adjust a frequency of the plurality of ASICs based on the target pass rate and the target throughput; and
adjust a voltage supplied to the plurality of ASICs.

Example X28 includes the SoC of example X27 or some other example herein, wherein adjusting the voltage supplied to the plurality of ASICs includes increasing the voltage supplied to the plurality of ASICs until a voltage associated with a stack of ASICS connected in parallel meets a minimum predetermined voltage.

Example X29 includes the SoC of example X28 or some other example herein, wherein adjusting the voltage supplied to the plurality of ASICs includes assigning respective test jobs to a subset of ASIC engines in the stack to prevent the subset of ASIC engines from idling subsequent to the voltage associated with the stack meeting the minimum predetermined voltage.

Example X30 includes the SoC of example X28 or some other example herein, wherein the voltage supplied to the plurality of ASICs is initially about 3000 mV, and wherein the voltage supplied to the plurality of ASICs is increased in increments of about 333 mV.

Example Z01 may include an apparatus comprising means to perform one or more elements of a method described in or related to any of examples 1-X30, or any other method or process described herein.

Example Z02 may include one or more non-transitory computer-readable media comprising instructions to cause an electronic device, upon execution of the instructions by one or more processors of the electronic device, to perform one or more elements of a method described in or related to any of examples 1-X30, or any other method or process described herein.

Example Z03 may include an apparatus comprising logic, modules, or circuitry to perform one or more elements of a method described in or related to any of examples 1-X30, or any other method or process described herein.

Example Z04 may include a method, technique, or process as described in or related to any of examples 1-X30, or portions or parts thereof.

Example Z05 may include an apparatus comprising: one or more processors and one or more computer-readable media comprising instructions that, when executed by the one or more processors, cause the one or more processors to perform the method, techniques, or process as described in or related to any of examples 1-X30, or portions thereof.

Example Z06 may include a computer program comprising instructions, wherein execution of the program by a processing element is to cause the processing element to carry out the method, techniques, or process as described in or related to any of examples 1-X30, or portions thereof.

Any of the above-described examples may be combined with any other example (or combination of examples), unless explicitly stated otherwise. The foregoing description of one or more implementations provides illustration and description, but is not intended to be exhaustive or to limit the scope of embodiments to the precise form disclosed. Modifications and variations are possible in light of the above teachings or may be acquired from practice of various embodiments.

Although certain embodiments have been illustrated and described herein for purposes of description, this application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. An apparatus comprising:
memory to store initialization information for a plurality of application-specific integrated circuits (ASICs); and
processing circuitry, coupled with the memory, to:
retrieve the initialization information from the memory, wherein the initialization information includes an indication of a target die temperature, a target pass rate, and a target throughput;
adjust an average die temperature of the plurality of ASICs based on the target die temperature;
adjust a frequency of the plurality of ASICs based on the target pass rate and the target throughput; and
adjust a voltage supplied to the plurality of ASICs.

2. The apparatus of claim 1, wherein adjusting the average die temperature of the plurality of ASICs includes dynamically adjusting a speed of one or more fans.

3. The apparatus of claim 1, wherein adjusting the frequency of the plurality of ASICs includes performing a coarse frequency tuning procedure, and wherein the processing circuitry is further to perform a fine frequency tuning procedure on the plurality of ASICs subsequent to the coarse frequency tuning procedure.

4. The apparatus of claim 3, wherein the coarse frequency tuning procedure includes adjusting the frequency of the plurality of ASICs by a first adjustment step, and wherein the fine frequency tuning procedure includes adjusting the frequency of the plurality of ASICs by a second adjustment step that is less than the first adjustment step.

5. The apparatus of claim 3, wherein the coarse frequency tuning procedure includes determining a pass rate associated with a known job for an ASIC from the plurality of ASICs, and adjusting the frequency of the plurality of ASICs based on a comparison of the determined pass rate to the target pass rate.

6. The apparatus of claim 3, wherein the coarse frequency tuning procedure includes:
determining that an overall throughput for the plurality of ASICs is lower than the target throughput; and
determining a frequency adjustment value to achieve the target throughput.

7. The apparatus of claim 6, wherein the determined frequency adjustment value is lower than the second adjust step, and wherein the processing circuitry is further to increase the voltage supplied to the plurality of ASICs to achieve the target throughput.

8. The apparatus of claim 1, wherein adjusting the voltage supplied to the plurality of ASICs includes determining an average pass rate associated with a known job for the plurality of ASICs and adjusting the voltage supplied to the plurality of ASICs based on a comparison of the determined average pass rate to the target pass rate.

9. The apparatus of claim 1, wherein adjusting the voltage supplied to the plurality of ASICs includes increasing the voltage supplied to the plurality of ASICs until a voltage associated with a stack of ASICS connected in parallel meets a minimum predetermined voltage.

10. The apparatus of claim 9, wherein adjusting the voltage supplied to the plurality of ASICs includes assigning respective test jobs to a subset of ASIC engines in the stack to prevent the subset of ASIC engines from idling subsequent to the voltage associated with the stack meeting the minimum predetermined voltage.

11. The apparatus of claim 9, wherein the voltage supplied to the plurality of ASICs is initially about 3000 mV, and wherein the voltage supplied to the plurality of ASICs is increased in increments of about 333 mV.

12. The apparatus of claim 9, wherein the minimum predetermined voltage is about 375 mV.

13. The apparatus of claim 1, wherein the apparatus comprises a controller coupled to the plurality of ASICs via a communications interface.

14. One or more computer-readable media storing instructions that, when executed by one or more processors, cause a controller to:
determine initialization information for a plurality of application-specific integrated circuits (ASICs), wherein the initialization information includes an indication of:
a target die temperature, a target pass rate, and a target throughput;
adjust an average die temperature of the plurality of ASICs based on the target die temperature;
adjust a frequency of the plurality of ASICs based on the target pass rate and the target throughput; and
adjust a voltage supplied to the plurality of ASICs.

15. The one or more computer-readable media of claim 14, wherein adjusting the average die temperature of the plurality of ASICs includes dynamically adjusting a speed of one or more fans.

16. The one or more computer-readable media of claim 14, wherein adjusting the frequency of the plurality of ASICs includes performing a coarse frequency tuning procedure, and wherein the processing circuitry is further to perform a fine frequency tuning procedure on the plurality of ASICs subsequent to the coarse frequency tuning procedure.

17. The one or more computer-readable media of claim 16, wherein the coarse frequency tuning procedure includes adjusting the frequency of the plurality of ASICs by a first adjustment step, and wherein the fine frequency tuning procedure includes adjusting the frequency of the plurality of ASICs by a second adjustment step that is less than the first adjustment step.

18-26. (canceled)

27. A system on a chip (SoC) comprising:
one or more processors; and
memory coupled to the one or more processors and storing instructions that, when executed by the one or more processors, cause the SoC to:
determine initialization information for a plurality of application-specific integrated circuits (ASICs), wherein the initialization information includes an indication of: a target die temperature, a target pass rate, and a target throughput;
adjust an average die temperature of the plurality of ASICs based on the target die temperature;
adjust a frequency of the plurality of ASICs based on the target pass rate and the target throughput; and
adjust a voltage supplied to the plurality of ASICs.

28. The SoC of claim 27, wherein adjusting the voltage supplied to the plurality of ASICs includes increasing the voltage supplied to the plurality of ASICs until a voltage associated with a stack of ASICS connected in parallel meets a minimum predetermined voltage.

29. The SoC of claim 28, wherein adjusting the voltage supplied to the plurality of ASICs includes assigning respective test jobs to a subset of ASIC engines in the stack to prevent the subset of ASIC engines from idling subsequent to the voltage associated with the stack meeting the minimum predetermined voltage.

30. (canceled)
